(19) United States
(12) Patent Application Publication
(10) Pub. No.: US 2024/0426377 A1
(43) Pub. Date: Dec. 26, 2024

(54) SEAL ASSEMBLY, SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Masamichi YACHI, Toyama-shi (JP); Ryosuke TAKAHASHI, Toyama-shi (JP); Masakazu SAKATA, Toyama-shi (JP)

(73) Assignee: KOKUSAI ELECTRIC CORPORATION, Tokyo (JP)

(21) Appl. No.: 18/829,717

(22) Filed: Sep. 10, 2024

Related U.S. Application Data
(63) Continuation of application No. PCT/JP2022/010968, filed on Mar. 11, 2022.

(51) Int. Cl. F16J 15/10; H01L 21/67

(52) U.S. Cl. CPC F16J 15/104; H01L 21/67109

(57) ABSTRACT

Provided is a technique including: a seal ring that seals flanges of a joint; an inner ring that is disposed on an inner peripheral side of the seal ring and restricts movement or deformation of the seal ring toward the inner peripheral side; and an outer ring that is disposed on an outer peripheral side of the seal ring and restricts movement or deformation of the seal ring toward the outer peripheral side, in which a plurality of spaces for receiving thermal expansion of a volume of the seal ring is provided in a circumferential direction between the inner ring and the outer ring.

### CROSS-REFERENCE TO RELATED APPLICATION

This application is a Bypass Continuation Application of PCT International Application No. PCT/JP2022/010968, filed on Mar. 11, 2022, the entire contents of which are incorporated herein by reference.

### TECHNICAL FIELD

The present disclosure relates to a Seal assembly, a substrate processing apparatus, method of processing a substrate, a method of manufacturing a semiconductor device, and a recording medium.

### BACKGROUND OF THE INVENTION

A joint portion between pipes has a structure in which an O-ring (seal ring) for making the joint portion of the pipes airtight, an inner center ring (inner ring) and an outer center ring (outer ring) for fixing the O-ring are sandwiched between flanges on both sides for jointing the pipes, and in this case, it is required to reduce seal ring cracking due to thermal expansion of the seal ring when a substrate is processed.

### SUMMARY OF THE INVENTION

The present disclosure provides a technique capable of reducing seal ring cracking when a substrate is processed.

According to one aspect of the present disclosure,
a technique is provided, the technique including: a seal ring that seals flanges of a joint; an inner ring that is disposed on an inner peripheral side of the seal ring and restricts movement or deformation of the seal ring toward the inner peripheral side; and an outer ring that is disposed on an outer peripheral side of the seal ring and restricts movement or deformation of the seal ring toward the outer peripheral side, in which a plurality of spaces for receiving thermal expansion of a volume of the seal ring is provided in a circumferential direction between the inner ring and the outer ring.

### BRIEF DESCRIPTION OF DRAWINGS

FIG. 1 is a vertical cross-sectional view schematically illustrating a vertical processing furnace of a substrate processing apparatus according to one embodiment of the present disclosure.

FIG. 2 is a schematic horizontal cross-sectional view taken along a line A-A in FIG. 1.

FIG. 3 is a plan view of a seal assembly in one embodiment of the present disclosure.

FIG. 4 is a cross-sectional view illustrating a portion where an outer ring of a pipe connection portion comes into contact with the seal ring according to one embodiment of the present disclosure.

FIG. 5 is a cross-sectional view illustrating a portion where the outer ring of the pipe connection portion is separated from the seal ring according to one embodiment of the present disclosure.

FIG. 6 is a cross-sectional view illustrating a comparative example of the pipe connection portion in one embodiment of the present disclosure.

FIG. 7 is a schematic configuration diagram of a controller of the substrate processing apparatus according to one embodiment of the present disclosure and is a block diagram illustrating a control system of a controller.

FIG. 8 is a flowchart of a method for manufacturing a semiconductor device according to one embodiment of the present disclosure.

FIG. 9 is a cross-sectional view illustrating a modified example of the pipe connection portion in one embodiment of the present disclosure.

FIG. 10 is a cross-sectional view illustrating a modified example of the pipe connection portion in one embodiment of the present disclosure.

FIG. 11 is a cross-sectional view illustrating a modified example of the pipe connection portion in one embodiment of the present disclosure.

FIG. 12 is a cross-sectional view illustrating a modified example of the pipe connection portion in one embodiment of the present disclosure.

### DETAILED DESCRIPTION

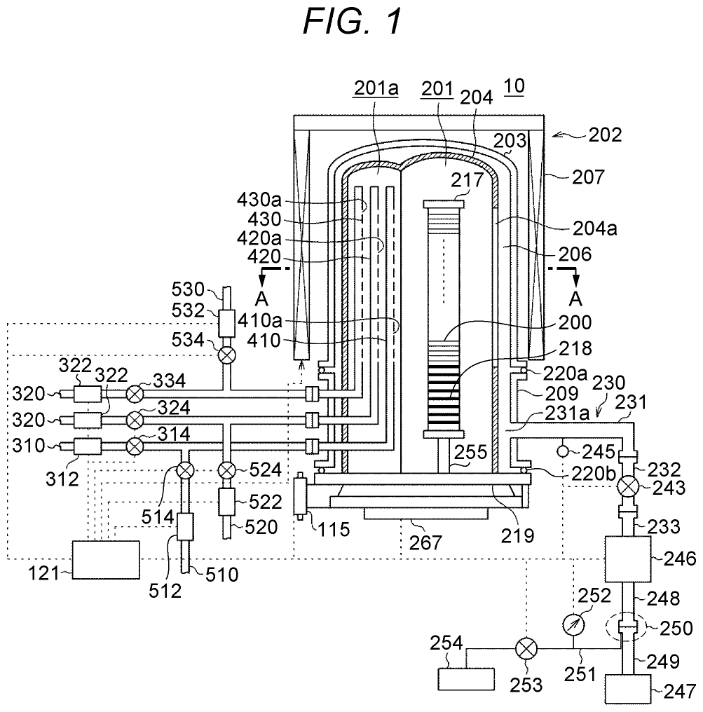

One aspect of the present disclosure will be hereinafter described mainly with reference to FIG. 1 to FIG. 8. Note that the drawings used in the following description are all schematic and thus, for example, a dimensional relationship between respective constituent elements and a ratio between the respective constituent elements illustrated in the drawings do not necessarily coincide with realities. In addition, for example, a plurality of drawings does not necessarily coincide with each other in the dimensional relationship between the respective constituent elements or in the ratio between the respective constituent elements.

### (1) Configuration of Substrate Processing Apparatus

A substrate processing apparatus 10 includes a processing furnace 202 including a heater 207 serving as a heating means (heating mechanism or heating system). The heater 207 has a cylindrical shape and is vertically installed by being supported by a heater base (not illustrated) serving as a holding plate.

An outer tube 203 constituting a reaction tube (a reaction vessel, a process vessel) is disposed inside the heater 207 concentrically with the heater 207. For example, the outer tube 203 is made of a heat-resistant material, such as quartz (SiO₂) or silicon carbide (SiC) and is formed in a cylindrical shape in which an upper end is closed and a lower end is open. Below the outer tube 203, a manifold (inlet flange) 209 is disposed concentrically with the outer tube 203. The manifold 209 is made of, for example, a metal such as stainless steel (SUS) and is formed in a cylindrical shape in which an upper end and a lower end are open. Between an upper end portion of the manifold 209 and the outer tube 203, an O-ring 220a serving as a seal member is disposed. When the manifold 209 is supported by the heater base, the outer tube 203 is vertically installed.

Inside the outer tube 203, an inner tube 204 constituting the reaction vessel is disposed. For example, the inner tube 204 is made of a heat-resistant material, such as quartz or Sic, and is formed in a cylindrical shape in which an upper end is closed and a lower end is open. The outer tube 203, the inner tube 204, and the manifold 209 mainly constitute the process vessel (reaction vessel). In a cylindrical hollow portion of the process vessel (inside the inner tube 204), a process chamber 201 is formed.

The process chamber 201 can accommodate wafers 200 serving as substrates in a state where the wafers 200 are arranged in multiple stages in the vertical direction in a horizontal posture by a boat 217 serving as a support.

In the process chamber 201, nozzles 410, 420, and 430 are disposed so as to penetrate a side wall of the manifold 209 and the inner tube 204. Gas supply pipes 310, 320, and 330 are connected to the nozzles 410, 420, and 430, respectively. Note that the processing furnace 202 of the present embodiment is not limited to the above-described form.

The gas supply pipes 310, 320, and 330 respectively include mass flow controller (MFC) 312, 322, and 332 which are flow rate controllers and valves 314, 324, and 334 which are on-off valves in order from the upstream side. To downstream sides of the valves 314, 324, and 334 of the gas supply pipes 310, 320, and 330, gas supply pipes 510, 520, and 530 that supply an inert gas are connected, respectively. MFCs 512, 522, and 532 which are flow rate controllers, and valves 514, 524, and 534 which are on-off valves, are disposed in the gas supply pipes 510, 520, and 530 in this order from the upstream side, respectively.

The nozzles 410, 420, and 430 are connected to tip portions of the gas supply pipes 310, 320, and 330, respectively. The nozzles 410, 420, and 430 are configured as L-shaped nozzles, and horizontal portions thereof are disposed so as to penetrate a side wall of the manifold 209 and the inner tube 204. Vertical portions of the nozzles 410, 420, and 430 are provided inside a channel-shaped (groove-shaped) preliminary chamber 201a which is formed so as to protrude outwardly in a radial direction of the inner tube 204 and to extend in the vertical direction. The vertical portions are provided in the preliminary chamber 201a so as to extend to the upper side (the upper side in the arrangement direction of the wafers 200) along the inner wall of the inner tube 204.

The nozzles 410, 420, and 430 are provided so as to extend from a lower region of the process chamber 201 to an upper region of the process chamber 201 and have a plurality of gas supply holes 410a, 420a, 430a that are provided at positions facing the wafers 200, respectively. By this means, a process gas is supplied from each of gas supply holes 410a, 420a, and 430a of the nozzles 410, 420, and 430 to the wafers 200. A plurality of gas supply holes 410a, 420a, and 430a are provided from a lower portion of the inner tube 204 to an upper portion thereof, have the same opening area, and are provided at the same opening pitch. However, the gas supply holes 410a, 420a, and 430a are not limited to the above-mentioned form. For example, the opening area may be gradually increased from the lower portion to the upper portion of the inner tube 204. This makes it possible to make a flow rate of the gas supplied from the gas supply holes 410a, 420a, and 430a more uniform.

The plurality of gas supply holes 410a, 420a, and 430a of the nozzles 410, 420, and 430 are provided at height positions from the lower portion to the upper portion of the boat 217, which will be described below. Thus, the process gas supplied from the gas supply holes 410a, 420a, and 430a of the nozzles 410, 420, and 430 into the process chamber 201 is supplied to the entire regions of the wafers 200 housed from the lower portion to the upper portion of the boat 217. The nozzles 410, 420, and 430 may be provided so as to extend from the lower region to the upper region of the process chamber 201 and are preferably provided so as to extend to the vicinity of a ceiling of the boat 217.

From the gas supply pipe 310, a source gas is supplied as the process gas into the process chamber 201 via the MFC 312, the valve 314, and the nozzle 410.

From the gas supply pipe 320, a reducing gas is supplied as the process gas into the process chamber 201 via the MFC 322, the valve 324, and the nozzle 420.

From the gas supply pipe 330, a gas containing a group 15 element different from the reducing gas is supplied as the process gas into the process chamber 201 via the MFC 332, the valve 334, and the nozzle 430.

From the gas supply pipes 510, 520, and 530, an inert gas is supplied into the process chamber 201 via the MFCs 512, 522, and 532, the valves 514, 524, and 534, and the nozzles 410, 420, and 430. As the inert gas, for example, a rare gas such as a nitrogen (N₂) gas, an argon (Ar) gas, a helium (He) gas, a neon (Ne) gas, or a xenon (Xe) gas can be used.

Mainly, in a case where the source gas is caused to flow from the gas supply pipe 310, the gas supply pipe 310, the MFC 312, and the valve 314 mainly constitute a source gas supply system, but the nozzle 410 may be included in the source gas supply system. The source gas supply system can also be referred to as a metal-containing gas supply system. In a case where the reducing gas is caused to flow from the gas supply pipe 320, the gas supply pipe 320, the MFC 322, and the valve 324 mainly constitute a reducing gas supply system, but the nozzle 420 may be included in the reducing gas supply system. In a case where the gas containing the group 15 element is caused to flow from the gas supply pipe 330, the gas supply pipe 330, the MFC 332, and the valve 334 mainly constitute a gas supply system containing the group 15 element, but the nozzle 430 may be included in the gas supply system containing the group 15 element. The metal-containing gas supply system, the reducing gas supply system, and the gas supply system containing the group 15 element can also be referred to as a process gas supply system. The nozzles 410, 420, and 430 may be included in the process gas supply system. The gas supply pipes 510, 520, and 530, the MFCs 512, 522, and 532, and the valves 514, 524, and 534 mainly constitute an inert gas supply system.

A gas supply method according to this embodiment transfers gas through the nozzles 410, 420, and 430 disposed in the preliminary chamber 201a in a vertically long space having an annular shape which is defined by the inner wall of the inner tube 204 and end portions of a plurality of wafers 200. Then, gas is ejected into the inner tube 204 from the plurality of gas supply holes 410a, 420a, and 430a of the nozzles 410, 420, and 430 which are provided at positions facing the wafers. More specifically, for example, the source gas, or the like, is ejected in a direction parallel to the surfaces of the wafers 200 through the gas supply hole 410a of the nozzle 410, the gas supply hole 420a of the nozzle 420, and the gas supply hole 430a of the nozzle 430.

An exhaust hole (exhaust port) 204a is a through-hole formed in a side wall of the inner tube 204 at a position facing the nozzles 410, 420, and 430 and is, for example, a slit-shaped through-hole open so as to be elongated in the vertical direction. The gas, which has been supplied into the process chamber 201 from the gas supply holes 410a, 420a, and 430a of the nozzles 410, 420, and 430 and has flowed on the surfaces of the wafers 200, flows into a gap (exhaust passage 206) formed between the inner tube 204 and the outer tube 203 through the exhaust hole 204a. Then, the gas that has flowed into the exhaust passage 206 flows into an exhaust pipe 230 and is discharged to the outside of the processing furnace 202.

The exhaust hole 204a is formed at a position facing the plurality of wafers 200, and the gas supplied from the gas supply holes 410a, 420a, and 430a to the vicinity of the wafers 200 in the process chamber 201 flows in the horizontal direction and then flows into the exhaust passage 206 via the exhaust hole 204a. The exhaust hole 204a is not limited to being configured as a slit-shaped through-hole and may be formed by a plurality of holes.

The manifold 209 is provided with the exhaust pipe 230 that discharges an atmosphere in the process chamber 201. The exhaust pipe 230 is configured by connecting a first pipe 231, a second pipe 232, and a third pipe 233 in this order from the upstream side. A pressure sensor 245 as a pressure detector that detects a pressure in the process chamber 201 is connected to the first pipe 231, an auto pressure controller (APC) valve 243 is connected to the second pipe 232, and a vacuum pump 246 as a vacuum exhaust device is connected to the third pipe 233. The APC valve 243 can perform vacuum exhaust and vacuum exhaust stop in the process chamber 201 by opening and closing the valve in a state where the vacuum pump 246 is operated, and furthermore, can adjust a pressure in the process chamber 201 by adjusting a degree of valve opening in a state where the vacuum pump 246 is operated. The exhaust hole 204a, the exhaust passage 206, the exhaust pipe 230, the APC valve 243, and the pressure sensor 245 mainly constitute an exhaust system. The vacuum pump 246 may be considered to be included in the exhaust system.

A seal cap 219 as a furnace opening lid capable of airtightly closing a lower end opening of the manifold 209 is provided below the manifold 209. The seal cap 219 is configured to abut against a lower end of the manifold 209 from a lower side in the vertical direction. The seal cap 219 is made of, for example, a metal such as SUS and is formed in a disk shape. On an upper surface of the seal cap 219, an O-ring 220b serving as a seal member abutting against the lower end of the manifold 209 is disposed. On a side of the seal cap 219 opposite to the process chamber 201, a rotation mechanism 267 that rotates the boat 217 that houses the wafers 200 is disposed. A rotation shaft 255 of the rotation mechanism 267 penetrates the seal cap 219 and is connected to the boat 217. The rotation mechanism 267 is configured to rotate the wafers 200 by rotating the boat 217. The seal cap 219 is configured to be lifted and lowered in the vertical direction by a boat elevator 115 serving as a lifting/lowering mechanism vertically disposed outside the outer tube 203. The boat elevator 115 is configured to be able to load the boat 217 into the process chamber 201 and unload the boat 217 out of the process chamber 201 by lifting and lowering the seal cap 219. The boat elevator 115 is configured as a transfer device (a transfer mechanism, a transfer system) that transfers the boat 217 and the wafers 200 housed in the boat 217 to the inside and the outside of the process chamber 201.

The boat 217 is configured such that a plurality of, for example, 25 to 200 wafers 200 are arranged at intervals in the vertical direction in a horizontal posture in a state where the centers thereof are aligned with each other. The boat 217 is made of, for example, a heat-resistant material such as quartz or SiC. The boat 217 has a lower portion that supports dummy plates 218 made of a heat-resistant material, such as quartz or Sic, in multiple stages in a horizontal posture. With this configuration, heat from the heater 207 is less likely to be transferred to the seal cap 219 side. Note that the present embodiment is not limited to the above-described form. For example, a heat insulating tube configured as a cylindrical member made of a heat-resistant material such as quartz or SiC may be disposed without disposing the dummy plates 218 at the lower portion of the boat 217.

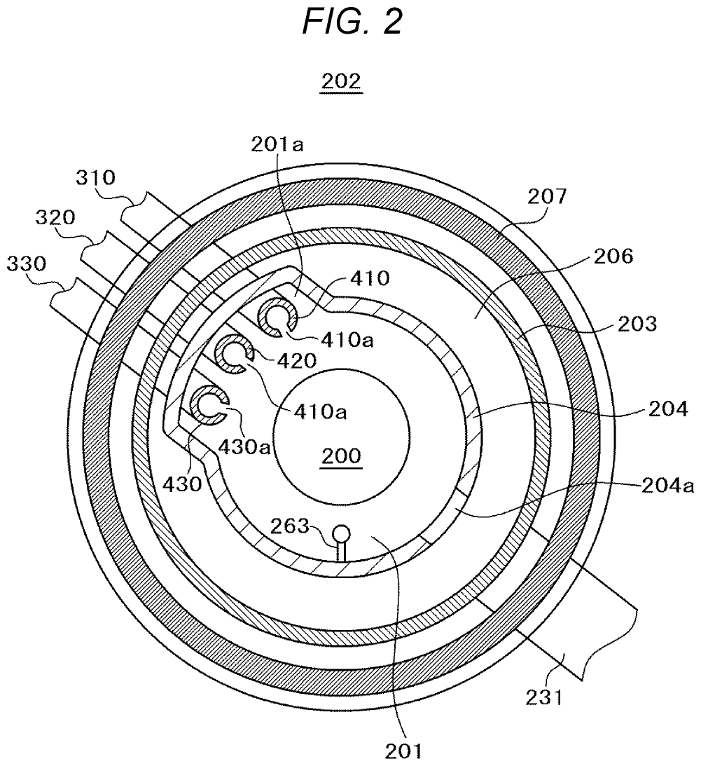

As illustrated in FIG. 2, a temperature sensor 263 serving as a temperature detector is disposed in the inner tube 204 and is configured such that a temperature in the process chamber 201 has a desired temperature distribution by adjusting an energization amount to the heater 207 based on temperature information detected by the temperature sensor 263. The temperature sensor 263 is formed in an L-shape similarly to the nozzles 410, 420, and 430 and is provided along the inner wall of the inner tube 204.

As illustrated in FIG. 1, on the downstream side of the vacuum pump 246, a detoxifying device 247 for processing harmful or combustible gas (for example, special high-pressure gas or hydrogen), or the like, is provided. By providing the detoxifying device 247, safety is improved. The vacuum pump 246 is provided with a pipe 248 for connection with the detoxifying device 247. The detoxifying device 247 is provided with a pipe 249 for connection with the vacuum pump 246. The vacuum pump 246, the detoxifying device 247, and the pipes 248, and 249 may be included in the exhaust system.

A communication hole pipe 251 is connected to a pipe connection portion 250 connecting the pipe 248 and the pipe 249. A pressure sensor 252 that measures an internal pressure of the communication hole pipe 251, a valve 253, and an exhaust device 254 are connected to the communication hole pipe 251 in order from the upstream side. The valve 253 fluidly connects the communication hole pipe 251 to the exhaust device 254 so as to be able to be open and closed. With this configuration, the controller 121 can control opening and closing of the valve 253 so as to keep the pressure measured by the pressure sensor 252 in a predetermined pressure range smaller than pressures in the pipes 248, and 249.

### (Pipe Connection Portion)

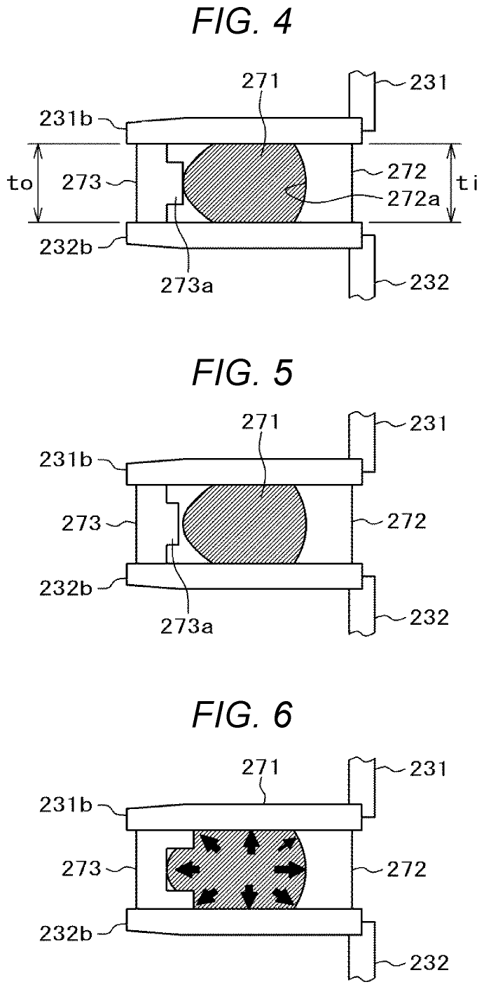

As illustrated in FIG. 4, the first pipe 231 of the exhaust pipe 230 has a flange 231b, and the second pipe 232 has a flange 232b. The flange 231b and the flange 232b face each other and are sealed by the seal ring 271, the inner ring 272, and the outer ring 273, so that the first pipe 231 and the second pipe 232 are connected. The seal ring 271, the inner ring 272, and the outer ring 273 constitute a seal assembly 270. The seal assembly 270 and the flanges 231b and 232b constitute a joint (pipe connection portion). The second pipe 232 and the third pipe 233 are similarly connected.

The seal ring 271 is an O-ring containing an elastomer and having a substantially circular cross-section. The seal ring 271 has a diameter such that the seal ring 271 contacts the flange 231b and the flange 232b in an annular region in which a surface of the flange 231b is closest to the facing flange 232b. This makes it possible to seal the flanges 231b and 232b.

The inner ring 272 is disposed on the inner peripheral side of the seal ring 271, and an outer peripheral surface 272a is formed in a circular shape so that the seal ring 271 is fitted. As a result, the seal ring 271 can be restricted from moving or deforming toward the inner peripheral side.

The outer ring 273 is disposed on the outer peripheral side of the seal ring 271, and the inner peripheral side has a cross-section having a convex shape convex in a direction of the seal ring 271 (inner peripheral side). As a result, the seal ring 271 can be restricted from moving or deforming toward the outer peripheral side.

A thickness (to) of the outer ring 273 is formed to be slightly smaller than a thickness (ti) of the inner ring 272. As a result, the outer ring 273 is autonomously positioned by elastic force of the seal ring 271. The joint in the present embodiment is a clamp joint such as NW quick coupling in which the flanges 231b and 232b are fastened and fixed by a clamp (not illustrated).

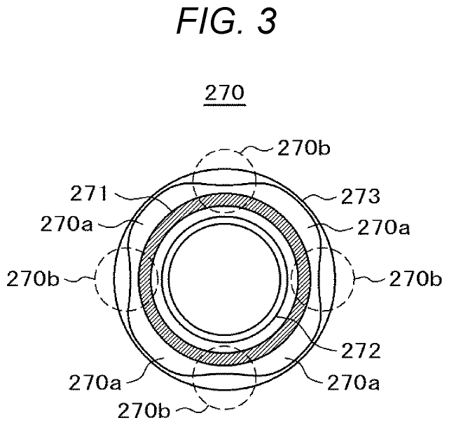

As illustrated in FIG. 3, a space 270a for receiving thermal expansion of a volume of the seal ring 271 is periodically provided in a circumferential direction between the inner ring 272 and the outer ring 273. For example, an inner peripheral surface of the outer ring 273 is formed to wave with a predetermined period in a radial direction with respect to a perfect circle. The outer ring 273 is formed to have a large wall thickness at a portion indicated by a broken line 270b and approaches the seal ring 271. In the broken line 270b in FIG. 3, as illustrated in FIGS. 4 and 5, a height of a protrusion 273a in a convex shape of the outer ring 273 changes in the circumferential direction. The outer ring 273 may have, for example, a shape of three-fold to four-fold rotational symmetry. In this case, the outer ring 273 can support the outer ring of the seal ring 271 at three to four portions and can reduce contact portions with the seal ring 271. Note that instead of or in addition to the inner peripheral surface of the outer ring 273, an outer peripheral surface of the inner ring may be formed to wave with a predetermined period in the radial direction with respect to the perfect circle. The period is preferably equal to or greater than three, but if the period is too great, a curvature of meandering becomes too small as compared with a wire diameter of the seal ring, and the seal ring cannot meander.

With such a configuration, the outer ring 273 comes into contact with part of the outer periphery of the seal ring 271, which is not the whole, at room temperature. In other words, the outer ring 273 has a portion (contact portion) in contact with the seal ring 271 and a portion (non-contact portion) separated from the seal ring 271. A ratio of the free cross-sectional area obtained by excluding a cross-sectional area of the seal ring 271 from a cross-sectional area of the space between the inner ring 272 and the outer ring 273 to a cross-sectional area of the seal ring 271 is, for example, 1:10 or more in the non-contact portion, and the ratio is not limited in the contact portion. Here, as the cross-sectional area of the seal ring 271, a cross-sectional area in a non-pressed state, that is, a free state is used. Further, the seal ring 271 meanders in the space between the inner ring 272 and the outer ring 273 when the seal ring 271 is heated at a temperature higher than the room temperature. As a result, an amount of crushing of the seal ring 271 by the outer ring 273 is reduced, so that breakage can be reduced.

### Comparative Example

As a configuration of the pipe connection portion, a structure in which the outer ring 273 holds the seal ring 271 circumferentially is considered. As illustrated in FIG. 6, if the seal ring 271 thermally expands, the cross-sectional area increased by the expansion of the seal ring 271 exceeds a space area obtained by excluding the cross-sectional area of the seal ring 271 before the expansion from the cross-sectional area of the space between the outer ring 273 and the inner ring 272, and there is no space to escape. The outer ring 273 in the comparative example has a cross-section having a concave shape concave to the inner peripheral side. Thus, an edge is formed on the inner peripheral side of the outer ring 273. This may generate a crack as a result of the seal ring 271 being pressed against the edge.

On the other hand, in the present embodiment, by reducing the contact with the seal ring 271 while maintaining external transmission and an electrothermal effect while leaving the outer ring, there is an escape space (free space) when the seal ring 271 expands, and the amount of crushing at the portion where the seal ring 271 is pressed against the outer ring 273 is alleviated, so that occurrence of cracks can be reduced. As a result, breakage due to thermal expansion of the seal ring 271 can be reduced, and a transmission risk can be reduced even at the time of high temperature specification.

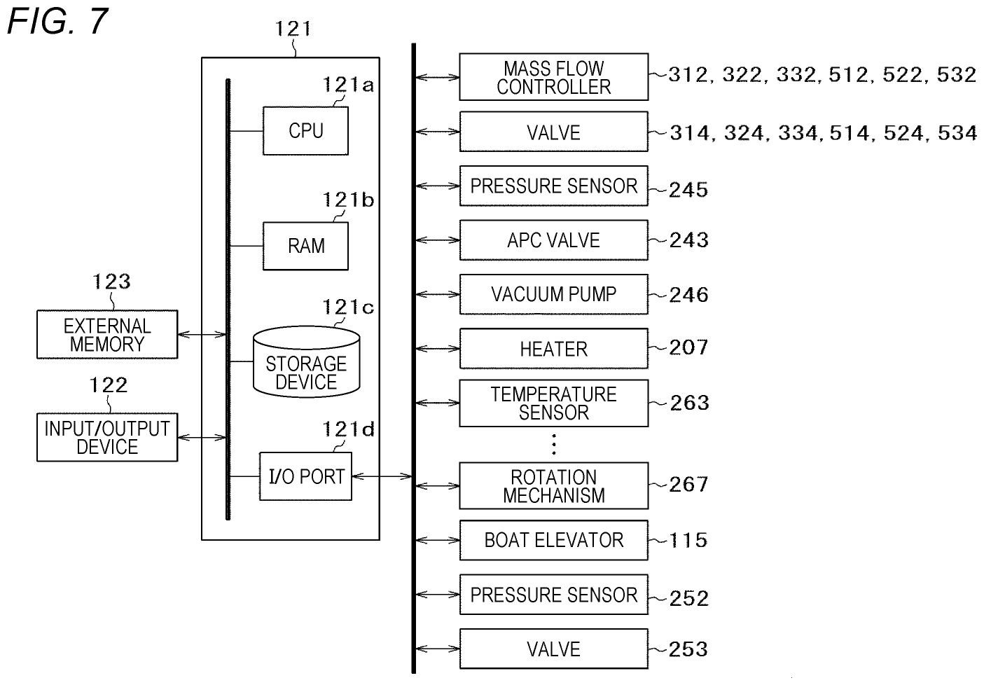

As illustrated in FIG. 7, a controller 121 which is a controller (control means, a controller) is formed as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus. An input/output device 122 formed as, for example, a touch panel, and the like, is connected to the controller 121.

The memory 121c includes, for example, a flash memory or a hard disk drive (HDD). In the memory 121c, a control program that controls operation of the substrate processing apparatus, a process recipe in which procedure, a condition, and the like, of a method of manufacturing a semiconductor device (substrate processing method) described later are described, and the like, are readably stored. The process recipe is a combination formed so as to cause the controller 121 to execute steps in a method of manufacturing a semiconductor device (substrate processing method) described later to obtain a predetermined result, and functions as a program. Hereinafter, the process recipe, the control program, and the like, are also collectively and simply referred to as a program. In the present specification, a term “program” may include only the process recipe alone, only the control program alone, or a combination of the process recipe and the control program. The RAM 121b is formed as a memory area (work area) in which programs, data, and the like, read by the CPU 121a are temporarily stored.

The I/O port 121d is connected to the MFCs 312, 322, 332, 512, 522, and 532, the valves 314, 324, 334, 514, 524, 534, and 253, the pressure sensors 245 and 252, the APC valve 243, the vacuum pump 246, the heater 207, the temperature sensor 263, the rotation mechanism 267, the boat elevator 115, and the like, described above.

The CPU 121a is configured to read the control program from the memory 121c to execute the control program and to read a recipe, and the like, from the memory 121c in response to an input of an operation command from the input/output device 122, and the like. The CPU 121a is configured to be able to control flow rate adjustment operation of various gases by the MFCs 312, 322, 332, 512, 522, and 532, opening/closing operation of the valves 314, 324, 334, 514, 524, and 534, opening/closing operation of the APC valve 243, pressure adjustment operation based on the pressure sensor 245 by the APC valve 243, opening/closing operation of the valve 253 based on the pressure sensor 252, temperature adjustment operation of the heater 207 based on the temperature sensor 263, start and stop of the vacuum pump 246, rotation and rotation speed adjustment operation of the boat 217 by the rotation mechanism 267, lifting/lowering operation of the boat 217 by the boat elevator 115, housing operation of the wafers 200 in the boat 217, and the like, according to the content of the read recipe.

The controller 121 can be configured by installing the above-described program stored in the external memory (for example, a magnetic tape, a magnetic disk such as a flexible disk or a hard disk, an optical disk such as a CD or a DVD, a magneto-optical disk such as an MO disk, or a semiconductor memory such as a USB memory or a memory card) 123 in a computer. The memory 121c and the external memory 123 are configured as computer-readable recording media. Hereinafter, the memory 121c and the external memory 123 are collectively and simply referred to as a recording medium. In the present specification, a term “recording medium” may include only the memory 121c alone, only the external memory 123 alone, or both of these. A program may be provided to a computer using a communication means such as the Internet or a dedicated line without using the external memory 123.

### (2) Substrate Processing Process

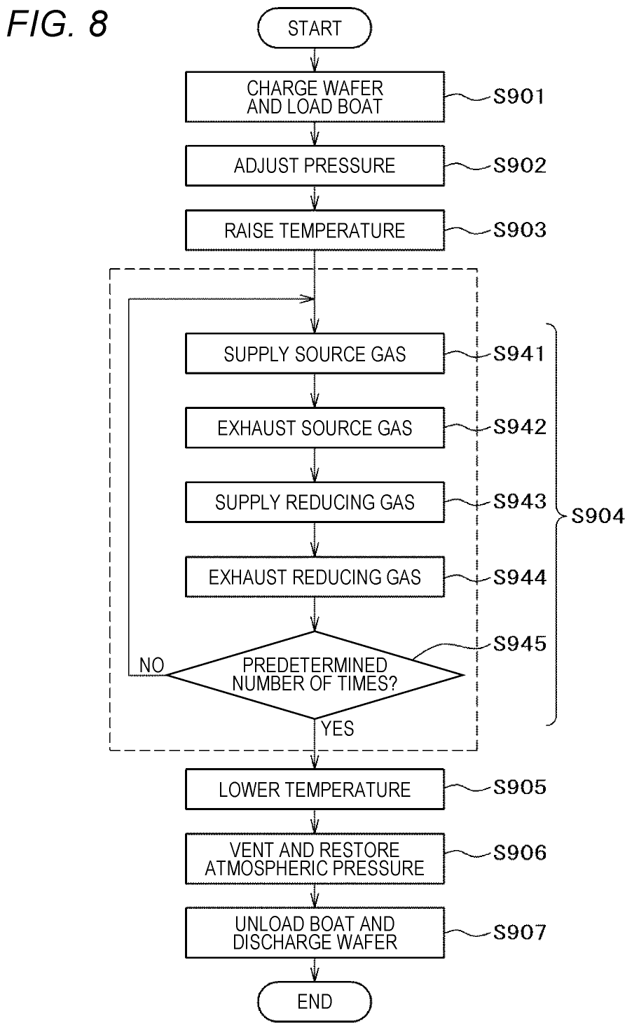

An example in which a predetermined film is formed on the wafers 200 using the source gas and the reducing gas will be described below with reference to FIG. 8. Note that in the following description, operation of the respective sections constituting the substrate processing apparatus is controlled by the controller 121.

In film forming processing in the present embodiment, a film is formed on the wafers 200 by performing a predetermined number of times (one or more times) of a cycle of non-simultaneously performing a process of supplying the source gas to the wafers 200 in the process chamber 201 (S941), a process of removing the source gas (residual gas) from the process chamber 201 (S942), a process of supplying the reducing gas to the wafers 200 in the process chamber 201 (S943), and a process of removing the reducing gas (residual gas) from the process chamber 201 (S944).

In the present specification, a term “wafer” means not only “a wafer itself (bare wafer)” but also “a laminate (composite) of a wafer and a predetermined layer, film, or the like, formed on a surface of the wafer”. Similarly, a term “surface of the wafer” may mean “surface of the wafer itself” or “a surface of a predetermined layer, film, or the like, formed on the wafer, that is, an outermost surface of the wafer serving as a laminate”. Interpretation of a term “substrate” is also similar to the “wafer”.

### (S901: Charge Wafer and Load Boat)

First, if a plurality of wafers 200 is loaded (wafers are charged) into the boat 217, the lower end opening of the manifold 209 is opened. Thereafter, as illustrated in FIG. 1, the boat 217 that supports the plurality of wafers 200 is lifted by the boat elevator 115 and is loaded into the process chamber 201 (boat is load). In this state, the lower end of the manifold 209 is sealed by the seal cap 219 via the O-ring 220b.

### (S902: Adjust Pressure)

Then, the vacuum pump 246 performs vacuum exhaust (decompression exhaust) such that the process chamber 201 has its inside, namely, a space in which the wafers 200 are present, at a desired pressure (desired degree of vacuum). In this event, the pressure in the process chamber 201 is measured by the pressure sensor 245, and the APC valve 243 is feedback-controlled based on information on the measured pressure. The exhaust in the process chamber 201 is continuously performed at least until the processing on the wafers 200 is completed.

### (S903: Raise Temperature)

The heater 207 heats the wafers 200 in the process chamber 201 so that a temperature of the wafers 200 reaches a desired processing temperature. In this case, based on the temperature information detected by the temperature sensor 263, a degree of energization to the heater 207 is feedback-controlled in such a manner that a desired temperature distribution is obtained in the process chamber 201. In addition, the rotation mechanism 267 starts rotation of the wafers 200. The heating and the rotation of the wafers 200 in the process chamber 201 continue at least until the processing on the wafers 200 is completed.

### (S904: Film Forming Processing)

If the temperature in the process chamber 6 is stabilized at the preset processing temperature, the following four substeps, that is, S941, S942, S943, and S944 are sequentially executed. Meanwhile, during this time, the boat 217 is rotated by the rotation mechanism 267 via a rotation shaft 255, whereby the wafers 200 are rotated.

### (S941: Supply Source Gas)

In this step, the source gas is supplied to the wafers 200 in the process chamber 201 to form a first layer on the outermost surface of the wafers 200. Specifically, the valve 314 is opened to flow the source gas into the gas supply pipe 310. A flow rate of the source gas is adjusted by the MFC 312, the source gas is supplied to a processing region in the process chamber 201 through the gas supply hole 410a of the nozzle 410 and is exhausted from the exhaust pipe 230 through the exhaust port 231a. At the same time, the valve 514 is opened to allow an inert gas to flow into the gas supply pipe 510. A flow rate of the inert gas is adjusted by the MFC 512, and the inert gas is supplied to the processing region in the process chamber 201 together with the source gas through the gas supply hole 410a of the nozzle 410 and is exhausted from the exhaust pipe 230. At the same time, the inert gas is supplied to the processing region in the process chamber 201 through the gas supply holes 420a and 430a of the nozzles 420 and 430 and is exhausted from the exhaust pipe 230. In this event, the controller 121 performs constant pressure control while setting a first pressure as a target pressure.

### (S942: Exhaust Source Gas)

After the first layer is formed, the valve 314 is closed, supply of the source gas is stopped, and the APC valve 243 is fully opened. As a result, inside of the process chamber 201 is vacuum-exhausted, and the source gas remaining in the process chamber 201 and unreacted or after contributing to formation of the first layer is discharged from the process chamber 201. Note that the residual gas may be purged with the inert gas supplied into the process chamber 201 while the valve 514 is kept open. A flow rate of the purge gas from the nozzle 410 is set so as to make a partial pressure of a low-vapor-pressure gas lower than a saturated vapor pressure in the exhaust passage, or so that a flow velocity in the outer tube 203 becomes a velocity exceeding a diffusion velocity.

### (S943: Supply Reducing Gas)

After step S942 is completed, the valve 324 is opened to cause the reducing gas to flow into the gas supply pipe 320, and the reducing gas is supplied to the wafers 200 in the process chamber 201, that is, the first layer formed on the wafers 200. A flow rate of the reducing gas is adjusted by the MFC 322, and the reducing gas is supplied to the processing region in the process chamber 201 through the gas supply hole 420a of the nozzle 420 and is exhausted from the exhaust pipe 230 through the exhaust port 231a. At the same time, the valve 524 is opened to allow an inert gas to flow into the gas supply pipe 520. A flow rate of the inert gas is adjusted by the MFC 522, and the inert gas is supplied to the processing region in the process chamber 201 through the gas supply hole 420a of the nozzle 420 together with the reducing gas and is exhausted from the exhaust pipe 230 through the exhaust port 231a. At the same time, the inert gas is supplied to the processing region in the process chamber 201 through the gas supply holes 410a and 430a of the nozzles 410 and 430 and is exhausted from the exhaust pipe 230 through the exhaust port 231a. In this event, the controller 121 performs constant pressure control while setting a second pressure as the target pressure. The first pressure and the second pressure are, for example, 100 to 5000 Pa.

Here, the reducing gas is, for example, a gas composed of hydrogen (H). The gas is preferably a gas composed of hydrogen alone. Specifically, hydrogen (H₂) gas or deuterium (D₂) can be used. The hydrogen gas is a combustible gas.

### (S944: Exhaust Reducing Gas)

After a lapse of a predetermined period from start of supply of the reducing gas, the valve 324 is closed to stop supply of the reducing gas, and constant pressure control (that is, full opening control) to set the target pressure to 0 is performed. As a result, inside of the process chamber 201 is vacuum-exhausted, and an unreacted reducing gas remaining in the process chamber 201 or a reducing gas after contributing to formation of the first layer is discharged from the process chamber 201. In this event, as in step S942, a predetermined amount of inert gas can be supplied into the process chamber 201 as a purge gas. An ultimate pressure in exhaust of the source gas or in exhaust of the reducing gas is 100 Pa or less, and preferably 10 to 50 Pa. The pressure in the process chamber 201 may differ by 10 times or more between during supply and during exhaust.

### (S945: Implement Predetermined Number of Times)

A film having a predetermined composition and a predetermined film thickness can be formed on the wafers 200 by performing a predetermined number of times (n times) of cycles in which steps S941 to step S944 described above are sequentially performed without temporally overlapping.

### (S905: Lower Temperature)

In this step, the temperature adjustment in step S903 continued during the film forming processing is stopped or reset to a lower temperature as necessary, and the temperature in the process chamber 201 is gradually lowered.

### (S906: Vent and Restore Atmospheric Pressure)

After the film forming process is completed, the inert gas is supplied from each of the nozzles 410, 420, and 430 into the process chamber 201 and exhausted from the exhaust port 231a. The inert gas supplied from the nozzles 410, 420, and 430 acts as the purge gas, whereby inside of the process chamber 201 is purged, and the gas remaining in the process chamber 201, reaction by-products, and the like, are removed from the inside of the process chamber 201 (after purge). Thereafter, the atmosphere in the process chamber 201 is replaced with the inert gas (replacement with the inert gas), so that the pressure in the process chamber 201 is restored to a normal pressure (atmospheric pressure is restored).

### (S907: Unload Boat and Discharge Wafer)

Then, the boat elevator 115 lowers the seal cap 219, and the lower end of the manifold 209 is opened. Then, the processed wafers 200 are unloaded from the lower end of the manifold 209 to the outside of the outer tube 203 (boat is unload) while being supported by the boat 217. Thereafter, the processed wafers 200 are unloaded to the outside of the outer tube 203 and then taken out from the boat 217 (wafers are discharged).

According to the present embodiment, one or a plurality of effects below can be obtained.

(a) The outer ring has a shape that does not depend on a wire diameter (thickness of the cross-section) of the seal ring, so that it is possible to reduce breakage due to heat.

(b) A variation in attachment by an installation place or an operator is reduced, so that it is possible to reduce a risk of breakage of the seal ring.

(c) The pipe can be heated to the vicinity of a heat resisting temperature of the seal ring. This makes it possible to increase the temperature of pipe heating.

(d) As a result of the temperature of pipe heating becoming high, it is possible to perform high temperature process operation.

(e) As a result of the temperature of pipe heating becoming high, it is possible to heat the inside of the furnace and the pipes and make it difficult for by-products to adhere.

(f) By making it difficult for by-products to adhere to the inside of the furnace and the pipes, it is possible to perform a large flow rate process in which an amount of by-products of the inside of the furnace and the pipes increases.

(g) By making it difficult for by-products to adhere to the inside of the furnace and the pipes, it is possible to reduce a frequency of gas cleaning for removing by-products and reduce a downtime. This can improve productivity.

### (3) Other Embodiments

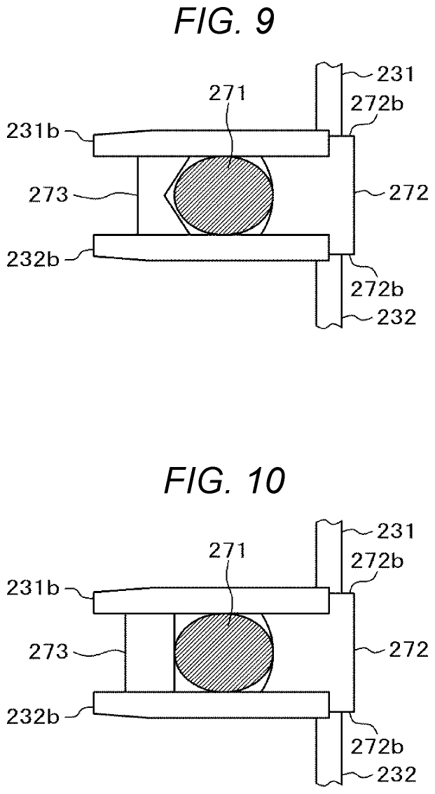

Next, modified examples of the pipe connection portion in the above-described embodiment will be described in detail with reference to FIGS. 9 to 12. In the following modified examples, only differences from the above-described embodiment will be described in detail.

### Modified Example 1

In the present modified example, as in the comparative example, the outer ring 273 holds the seal ring 271 circumferentially. However, in the present modified example, as illustrated in FIG. 9, a V-shaped outer ring 273 is provided instead of the outer ring having a U-shaped groove in the comparative example, and the inner ring 272 having an engagement portion is provided instead of the inner ring having no engagement portion. The engagement portion 272b of the inner ring 272 is engaged with the inner peripheral side of the flanges 231b and 232b and is positioned in a direction parallel to the surfaces of the flanges 231b and 232b. The outer ring 273 has a V-shaped valley shape on the inner peripheral side, and the inner ring 272 has a concave portion to which the seal ring 271 is fitted on the outer peripheral side. As a result, the seal ring 271 is fitted and sandwiched between the outer ring 273 and the inner ring 272. Although an escape space (free space) when the seal ring 271 expands is small, the outer ring 273 has no edge that damages the seal ring 271, so that it is possible to reduce breakage of the seal ring 271.

### Modified Example 2

In the present modified example, as illustrated in FIG. 10, the outer ring 273 having a flat surface whose inner peripheral side is perpendicular to the surfaces of the flanges is provided instead of the V-shaped outer ring in modified example 1. As a result, the seal ring 271 is sandwiched between the outer ring 273 and the inner ring 272. The free space is larger than that in Modified example 1, and the outer ring 273 has no edge that damages the seal ring 271, so that it is possible to reduce breakage of the seal ring 271.

### Modified Example 3

In the present modified example, as illustrated in FIG. 11, the outer ring 273 having an engagement portion is provided instead of the outer ring having no engagement portion in Modified example 2. An engagement portion 273b of the outer ring 273 is engaged with the outer peripheral sides of the flanges 231b and 232b and is positioned in a direction parallel to the surfaces of the flanges 231b and 232b. It is possible to distribute the free space appropriately along the seal ring 271. In addition, the free space can be expanded as the entire periphery is separated at room temperature.

### Modified Example 4

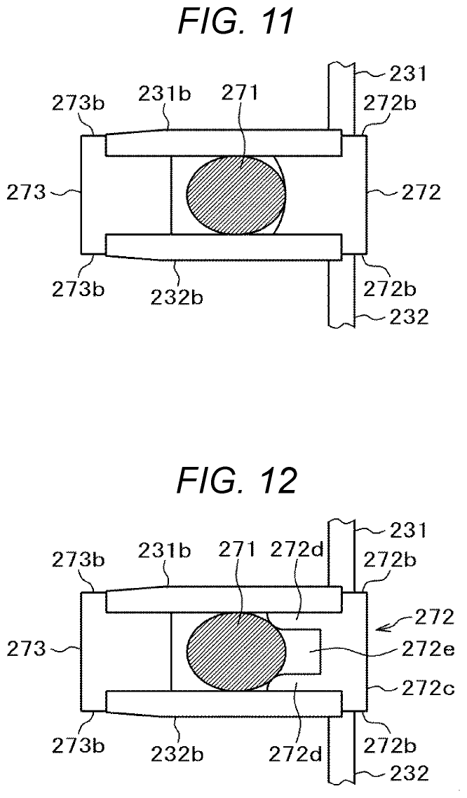

In the present modified example, as illustrated in FIG. 12, the inner ring 272 having a U-shaped groove is provided instead of the inner ring in Modified example 3. The inner ring 272 includes a base portion 272c having a rectangular cross-section forming an inner peripheral surface, and a pair of convex portions 272d, 272d extending from upper and lower sides of the base portion 272c along the surfaces of the flanges 231b and 232b toward the seal ring 271, and has an arc at a position where the convex portions 272d, 272d abut on the seal ring 271. A groove 272e is formed between the pair of convex portions 272d, 272d. The free space is larger than that in Modified example 3, and the inner ring 272 has no edge that damages the seal ring 271.

The above-described embodiment has also described the example of forming a film using the substrate processing apparatus which is a batch-type vertical apparatus configured to process a plurality of substrates at a time; however, the present disclosure is not limited to this example. The present disclosure is suitably applicable to a case of forming a film using a substrate processing apparatus of a single wafer type configured to process one or several substrates at a time. Even in a case of using this substrate processing apparatus, a film can be formed with a sequence and a processing condition similar to those in the above-described embodiment.

It is preferable to individually prepare (prepare a plurality of) process recipes (programs in which processing procedure, a processing condition, and the like, are described) to be used for forming these various thin films according to the content of substrate processing (film type, composition ratio, film quality, film thickness, processing procedure, processing condition, and the like, of a thin film to be formed). Then, when substrate processing is started, it is preferable to appropriately select an appropriate process recipe from among a plurality of process recipes according to the content of the substrate processing. Specifically, it is preferable to store (install) a plurality of process recipes individually prepared according to the contents of the substrate processing in advance in the memory 121c included in the substrate processing apparatus via a telecommunication line or a recording medium (external memory 123) in which the process recipes are recorded. Then, when the substrate processing is started, the CPU 121a included in the substrate processing apparatus preferably appropriately selects an appropriate process recipe from among the plurality of process recipes stored in the memory 121c according to the content of the substrate processing. With such a configuration, one substrate processing apparatus can generally form thin films of various film types, composition ratios, film qualities, and film thicknesses with good reproducibility. In addition, it is possible to reduce operation load (for example, input load of processing procedure, a processing condition, and the like) of an operator, and it is possible to quickly start the substrate processing while avoiding an operation error.

In addition, the present disclosure can also be implemented, for example, by changing a process recipe of an existing substrate processing apparatus. In a case where a process recipe is changed, the process recipe according to the present disclosure can be installed in an existing substrate processing apparatus via a telecommunication line or a recording medium in which the process recipe according to the present disclosure is recorded, or a process recipe itself of an existing substrate processing apparatus can be changed to the process recipe according to the present disclosure by operating an input/output device of the existing substrate processing apparatus.

The embodiment of the present disclosure has been specifically described above. However, the present disclosure is not limited to the embodiment described above, and thus various modified examples can be made without departing from the gist of the present disclosure.

According to one aspect of the present disclosure, it is possible to reduce seal ring cracking. Brief

What is claimed is:

1. A seal assembly comprising:
a seal ring that seals flanges of a joint;
an inner ring that is disposed on an inner peripheral side of the seal ring and restricts movement or deformation of the seal ring toward the inner peripheral side; and
an outer ring that is disposed on an outer peripheral side of the seal ring and restricts movement or deformation of the seal ring toward the outer peripheral side,
wherein a plurality of spaces for receiving thermal expansion of a volume of the seal ring is provided in a circumferential direction at a central portion in a thickness direction of an inner peripheral surface of the inner ring or an outer peripheral surface of the outer ring.

2. The seal assembly according to claim 1, wherein an inner peripheral surface of the outer ring or an outer peripheral surface of the inner ring is formed such that the central portion waves with a predetermined period in a radial direction with respect to a circle.

3. The seal assembly according to claim 1, wherein the seal assembly has a portion where a cross-sectional area between the inner ring and the outer ring is larger than a cross-sectional area of the seal ring when heated to a temperature higher than a room temperature.

4. The seal assembly according to claim 1, wherein an outer peripheral surface of the inner ring is formed in a circular shape.

5. The seal assembly according to claim 1, wherein the outer ring contacts part of the seal ring at room temperature.

6. The seal assembly according to claim 1, wherein the seal ring meanders in a space between the inner ring and the outer ring when heated to a temperature higher than a room temperature.

7. The seal assembly according to claim 1, wherein the seal ring a is an O-ring comprising an elastomer and having substantially circular cross-section, and has a diameter such that the seal ring contacts the flanges in an annular region in which a surface of the flange is closest to the facing flange.

8. The seal assembly according to claim 1, wherein the outer ring has an inner peripheral side having a flat surface perpendicular to surfaces of the flanges or a cross-section having a convex shape on the inner peripheral side.

9. The seal assembly according to claim 8, wherein a height of a protrusion having the convex shape of the outer ring changes in a circumferential direction.

10. The seal assembly according to claim 1, wherein the outer ring has a V-shaped valley shape on an inner peripheral side.

11. The seal assembly according to claim 1, wherein the outer ring has a shape of three-fold to four-fold rotational symmetry.

12. The seal assembly according to claim 1, wherein the outer ring has an engagement portion that is engaged with an outer periphery of one of the flanges, and positioning is performed in a direction parallel to surfaces of the flanges by the engagement portion.

13. The seal assembly according to claim 1, wherein a thickness of the outer ring is smaller than a thickness of the inner ring.

14. The seal assembly according to claim 1, wherein the central portion is formed perpendicular to surfaces of the flanges.

15. A substrate processing apparatus comprising a seal assembly comprising: a seal ring that seals flanges of a joint; an inner ring that is disposed on an inner peripheral side of the seal ring and restricts movement or deformation of the seal ring toward the inner peripheral side; and an outer ring that is disposed on an outer peripheral side of the seal ring and restricts movement or deformation of the seal ring toward the outer peripheral side, wherein a plurality of spaces for receiving thermal expansion of a volume of the seal ring is provided in a circumferential direction at a central portion in a thickness direction of an inner peripheral surface of the inner ring or an outer peripheral surface of the outer ring.

16. A substrate processing method comprising:
loading a substrate into a substrate processing apparatus including a seal assembly, the seal assembly including: a seal ring that seals flanges of a joint; an inner ring that is disposed on an inner peripheral side of the seal ring and restricts movement or deformation of the seal ring toward the inner peripheral side; and an outer ring that is disposed on an outer peripheral side of the seal ring and restricts movement or deformation of the seal ring toward the outer peripheral side, in which a plurality of spaces for receiving thermal expansion of a volume of the seal ring is provided in a circumferential direction at a central portion in a thickness direction of an inner peripheral surface of the inner ring or an outer peripheral surface of the outer ring; and
processing the substrate.

17. A method of manufacturing a semiconductor device comprising the method of claim 16.

18. A non-transitory computer-readable recording medium storing a program that causes, by a computer, a substrate processing apparatus to perform a process comprising the method of claim 16.
